(19) United States
(12) Patent Application Publication
(10) Pub. No.: US 2006/0277343 A1
(43) Pub. Date: Dec. 7, 2006

(54) Internal extra expansion slot

(76) Inventors: Yu-Sheng Lin, Taipei (TW); Hsiao-Tsu Ni, Hsinchuang City (TW)

Correspondence Address: RABIN & BERDO, P.C.;Suite 500, 1101 14 Street, N.W., Washington, DC, 20005, US

(21) Appl. No.: 11/326,385

(22) Filed: Jan. 6, 2006

(30) Foreign Application Priority Data
Jun. 7, 2005 (TW) 94118800

(51) Int. Cl. G06F 13/00; H05K 7/10

(52) U.S. Cl. 710/301

(57) ABSTRACT

An internal extra expansion slot for a server includes a baseboard, an expansion slot set, and an extra expansion slot. The expansion slot set is disposed on a portion of a card side of the baseboard, such that expansion slots are parallel to each other. The extra expansion slot is disposed on the opposite portion of the expansion slot set. The extra expansion slot set is parallel to the expansion slot set and set apart from the expansion slot set to avoid an interference between add-in cards on the extra expansion slot and the expansion slot set.

### RELATED APPLICATIONS

The present application is based on, and claims priority from, Taiwan Application Serial Number 94118800, filed Jun. 7, 2005, the disclosure of which is hereby incorporated by reference herein in its entirety.

### BACKGROUND

1. Field of Invention

The present invention relates to an internal extra expansion slot for a server. More particularly, the present invention relates to an internal extra expansion slot for a server with an EATX (Extended ATX) or SSI (Server Side Includes) motherboard.

2. Description of Related Art

In modern servers, various expansion slots are generally designed to be located on the side of a motherboard which is near the back panel, such as slots for a graphics card, audio card, SCSI card or other customized function expansion card. Most add-in cards have to be connected to external devices through cables. For example, a graphics card is connected to the display through a VGA signal cable. Such an add-in card is suited to be put in an appropriate expansion slot at a predefined position.

However, there are some applications where the device inside the chassis employs an interior cable instead of an exterior cable to connect with an interface card on an expansion slot, especially for storage devices which are often installed within a server, such as SATA (Serial ATA) adapter cards for SATA hard disk drives or RAID controller cards for RAID storage systems. Motherboards of EATX or SSI specification are commonly used in current server systems. Conventional expansion slots in compliance with these specifications are near the back panel of a chassis; therefore available interior space of the system is left unused and loses its extensibility.

If manufacturers intend to arrange interface connectors for devices right on the motherboard, the circuit layout needs to be modified, which is usually not easy to do because area on the motherboard is very limited. Therefore, selectivity in functions is also lost.

For the foregoing reasons, there is a need for an improved motherboard configuration without limitation from conventional specifications to provide flexibility in using various functions desired.

### SUMMARY

It is therefore an objective of the present invention to provide an internal extra expansion slot for a server so that the opposite area of the expansion slot on the motherboard under specification can be utilized fully.

It is another objective of the present invention to provide an internal extra expansion slot for a server for more flexibility of interior extensions.

In accordance with the foregoing and other objectives of the present invention, an internal extra expansion slot for a server is disclosed. The internal extra expansion slot includes a baseboard, an expansion slot set and an extra expansion slot. The expansion slot set is disposed on a portion of a card side of the baseboard and has a plurality of expansion slots such as four to seven. Axes of the expansion slots are parallel to each other.

The extra expansion slot is disposed on the opposite portion of the expansion slot set in the card side and is spaced a predefined distance apart from the expansion slot set along an expansion slot set axis for avoiding an interference between add-in cards. Preferably, the axis of the extra expansion slot is parallel to the expansion slot set axis.

According to a preferred embodiment of the present invention, the motherboard includes six expansion slots and an extra expansion slot. The extra expansion slot is disposed on the opposite portion of the expansion slot that is nearest to a long side of the motherboard.

In conclusion, the present invention makes full use of area of an SSI or EATX specification motherboard and provides more extensibility, for example, to storage devices in a server system requiring an SAS (Serial Attached SCSI) or SATA adapter card. Further, users can choose a desired add-in card to use so that flexibility in functional extensions is available.

It is to be understood that both the foregoing general description and the following detailed description are by examples and are intended to provide further explanation of the invention as claimed.

### BRIEF DESCRIPTION OF THE DRAWINGS

These and other features, aspects and advantages of the present invention will become better understood with regard to the following description, appended claims and accompanying drawings where:

FIG. 1 is a schematic diagram of an internal extra expansion slot for a server in accordance with a preferred embodiment of the present invention; and

FIG. 2 is a schematic diagram of applying the internal extra expansion slot in a server system.

### DESCRIPTION OF THE PREFERRED EMBODIMENTS

The present invention discloses an internal extra expansion slot which is disposed on the portion opposite to an expansion slot set on a motherboard under standard specification, making full use of the area on the motherboard and offering more functions. Also, the present invention applies to a server system with an EATX or SSI specified motherboard, and the motherboard may support PCI, PCI X, or PCI-E bus interfaces. Reference will now be made in detail to the present preferred embodiments of the invention, examples of which are illustrated in the accompanying drawings. Wherever possible, the same reference numbers are used in the drawings and the description to refer to the same or like parts.

An SSI standard motherboard, for example, defines a core side and a card side on a baseboard, and the expansion slot set of the invention is disposed on a portion of the card side which the specification indicates.

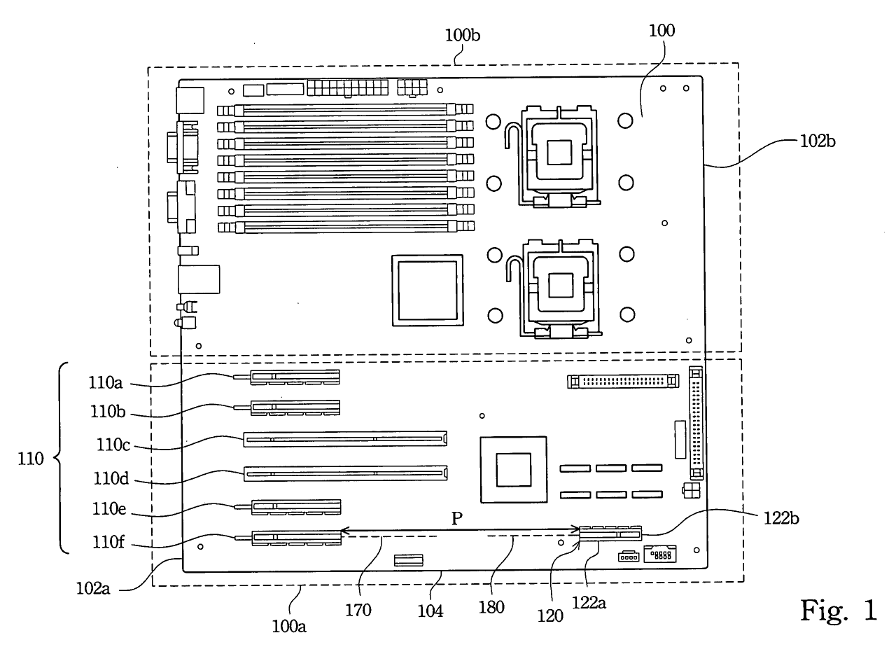

FIG. 1 is a schematic diagram of an internal extra expansion slot for a server in accordance with a preferred embodiment of the present invention. The internal extra expansion slot for a server includes a baseboard 100, an expansion slot set 110 and an extra expansion slot 120. The expansion slot set 110 is disposed on a portion of the card side of the baseboard which is near a back panel of a chassis, that is, on a baseboard short side 102a. The expansion slot set 110 may have a plurality of expansion slots, from four to seven, and axes of the expansion slots are parallel to each other.

The extra expansion slot 120 is disposed on the baseboard 100 and is spaced a predefined distance P apart from the expansion slot set 110 along an expansion slot set axis 170. In other words, the extra expansion slot 120 does not overlap the expansion slot set 110 in the perpendicular direction of the expansion slot set axis 170 and is on the opposite portion of the side near the back panel of the chassis, that is, opposite to the baseboard short side 102a. Preferably, an extra expansion slot axis 180 of the extra expansion slot 120 is parallel to the expansion slot set axis 170, or, the predefined distance P is half the length of a standard full length card or the length of a half length card for avoiding interference between add-in cards on the extra expansion slot 120 and the expansion slot set 110.

Herein, the expansion slot set axis and the extra expansion slot axis refer to imaginary lines which pass through centers of the expansion slot set and the extra expansion slot respectively and are parallel to the longer side of each slot.

In a preferred embodiment, a motherboard complies with the SSI specification whose dimension is 12 inches×13 inches, and the bus interface of the expansion slot set 110 and the extra expansion slot 120 may be a PCI X bus, PCI Express bus or PCI bus. The baseboard 100 includes six expansion slots 110a˜110f which compose an expansion slot set 110.

The baseboard 100 includes a card side 100a and a core side 100b. The expansion slot set 110 is disposed on a portion of the card side 100a that is near a first baseboard short side 102a, and axes of the expansion slots of which are parallel to each other. The expansion slot 110f is the slot nearest to a baseboard long side 104 of the baseboard 100 according to the SSI specification.

The extra expansion slot 120 is disposed on the portion opposite to the expansion slot set 110 in the card side 100a and is near a second baseboard short side 102b and does not overlap the expansion slot set 110 along the line perpendicular to the expansion slot set axis 170. For example, the extra expansion slot axis 180 is collinear with the expansion slot axis 170.

The extra expansion slot 120 is spaced a predefined distance P apart from the expansion slot 110f along the expansion slot set axis 170, and preferably, equals the half length of a standard full length card or the length of a half length card for avoiding an interference between add-in cards (not shown in the figure) on the extra expansion slot 120 and that on other expansion slots such as the expansion slot 110f.

When a half-length add-in card with a specific function, such as a graphics card, audio card or any other interface card for a peripheral device, is inserted in a slot of the expansion slot set, the extra expansion slot provides an additional way to use another half-length add-in card, such as a RAID card for a RAID storage system in a server or a SATA adapter card for a SATA storage drive. Because EATX or SSI motherboards enable two half-length add-in cards in length, disposition of the extra expansion slot makes full use of space within the chassis.

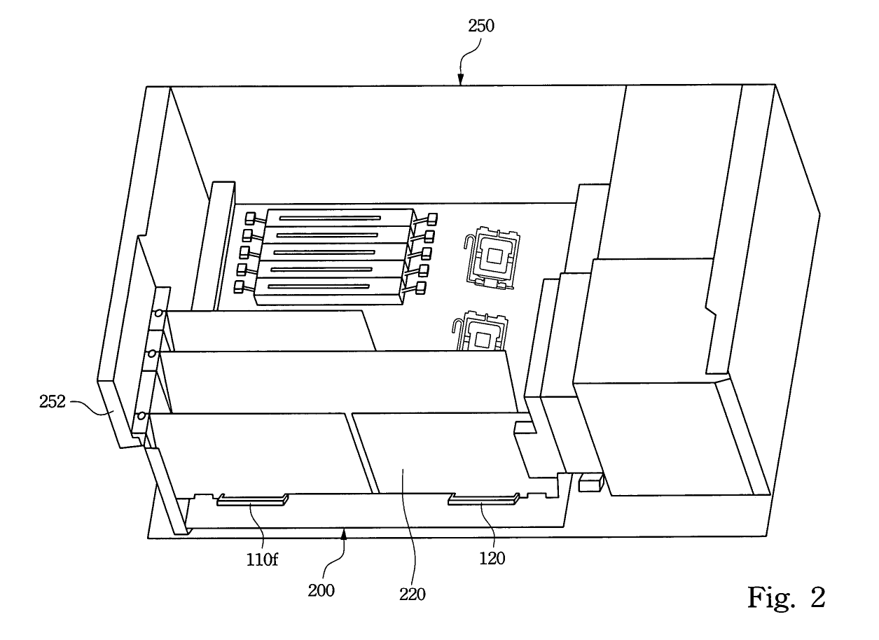

Reference is made to FIG. 2, which is a schematic diagram of applying the internal extra expansion slot in a server system. The figure shows that the motherboard 200 in the embodiment above is installed within a chassis 250 of the server system, and the expansion slot 110f is disposed between a back panel 252 and the extra expansion slot 120. In contrast to the expansion slot 110f, the extra expansion slot 120 is nearer to the inside of the chassis 250, holding an add-in card 220 that complies with half-length card specification. Compared with the conventional motherboard whose expansion slots are disposed on the portion near the back panel 252, the present invention provides an interior extensibility.

Though expansion slots in a server are described as six slots in the embodiment above, the number of the expansion slots on the SSI or EATX specification motherboard are not limited to this. As long as it is applicable for disposing an extra expansion slot, motherboards with any number of expansion slots under the specification above are considered falling within the scope of this invention.

The present invention has the following advantage. The present invention makes full use of the opposite portion of the expansion slots under specification by disposing at least an extra expansion slot for providing users with more flexibility in expanding functions. Users can install half-length add-in cards on the area closer to the inside of the chassis instead of the area near the back panel according to desires; and especially in application of adapter cards for storage devices such as a SATA or SAS adapter card or RAID cards in a server system, problems of complicated circuit and component layouts on the board and lack of functional expansion flexibility are resolved when various connectors for expansive functions are set right on the motherboard.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An internal extra expansion slot for a server applied to a motherboard complying with EATX or SSI specification, comprising:
a baseboard having a card side;
an expansion slot set having a plurality of expansion slots and disposed on a portion of the card side, wherein the axes of the expansion slots are parallel with each other; and
an extra expansion slot disposed on the opposite portion of the expansion slot set in the card side and spaced a predefined distance apart from the expansion slot set along an expansion slot set axis.

2. The internal extra expansion slot of claim 1, wherein a number of the expansion slots of the expansion slot set is four, five, six or seven.

3. The internal extra expansion slot of claim 1, wherein an extra expansion slot axis of the extra expansion slot and one of the axes of the expansion slots are collinear.

4. The internal extra expansion slot of claim 1, wherein the expansion slot set and/or the extra expansion slot is PCI Express, PCI X or PCI bus.

5. The internal extra expansion slot of claim 1, wherein an extra expansion slot axis of the extra expansion slot is parallel to the expansion slot set axis.

6. A server system with a motherboard complying with EATX or SSI specification, comprising:
a chassis having a back panel;
a baseboard installed within the chassis and having a card side;
an expansion slot set having a plurality of expansion slots and disposed on a portion of the card side, wherein the axes of the expansion slots are parallel to each other; and
an extra expansion slot disposed on the opposite portion of the expansion slot set in the card side,
wherein the expansion slot set is disposed between the back panel and the extra expansion slot, the extra expansion slot is spaced a predefined distance apart from the expansion slot set along an expansion slot set axis, and an extra expansion slot axis of the extra expansion slot is parallel to the expansion slot set axis.

7. The server system of claim 6, wherein a number of the expansion slots of the expansion slot set is four, five, six or seven.

8. The server system of claim 6, wherein the extra expansion slot axis and one of the axes of the expansion slots are collinear.

9. The server system of claim 6, wherein the expansion slot set and/or the extra expansion slot is PCI Express, PCI X or PCI bus.
